(19) United States
(12) Patent Application Publication
(10) Pub. No.: US 2010/0167543 A1
(43) Pub. Date: Jul. 1, 2010

(54) METHOD FOR MANUFACTURING SEMICONDUCTOR DEVICE

(76) Inventor: Gwan-Ha Kim, Gangnam-gu (KR)

Correspondence Address: SHERR & VAUGHN, PLLC, 620 HERNDON PARKWAY, SUITE 320, HERNDON, VA, 20170, US

(21) Appl. No.: 12/634,595

(22) Filed: Dec. 9, 2009

(30) Foreign Application Priority Data
Dec. 30, 2008 (KR) 10-2008-0137616

(51) Int. Cl. H01L 21/3205; C23C 14/34; B05C 11/00

(52) U.S. Cl. 438/685; 204/192.1; 118/37; 204/298.02; 257/E21.295

(57) ABSTRACT

A method for manufacturing a semiconductor power device may includes: performing a grinding process on a back side of a wafer, performing a first plasma process and a rapid thermal process sequentially after performing the grinding process, performing a second plasma process after performing the rapid thermal process, and performing a metal thin film process after performing the second plasma process. The method for manufacturing a semiconductor device may be capable of preventing a peeling effect from occurring on a wafer surface by removing hydrogen from the wafer surface by controlling surface roughness to a desired level by treating the wafer surface using hydrogen plasma and a rapid thermal process (RTP) after subjecting a backside of the wafer to a grinding process.

The present application claims priority under 35 U.S.C. 119 to Korean Patent Application No. 10-2008-0137616 (filed on Dec. 30, 2008), which is hereby incorporated by reference in its entirety.

### BACKGROUND

With the recent rapid advancement of the information and communication society, power semiconductor device technologies for information and communication have been recognized as key factors for automation, downsizing/lightness, low noise, high reliability, and high energy efficiency of a variety of systems, including information and communication systems. Also, these power technologies have become key to creating a variety of high value-added high-tech electronic equipment and facilities such as vehicles, home appliances, industrial equipment, industrial facilities, and SOC (social overhead capital) infrastructures (electric railways and the like).

In manufacturing power devices using a semiconductor wafer, metal is deposited on the backside of the wafer, and utilized as a body. In particular, a process of polishing and thinning the wafer is used to overcome heat generation problems, and improve characteristics of the power devices. Then, the metal may be formed on the backside of the wafer. In this case, adhesion of the formed metal may be weakened and the metal film may have problems with peeling.

For the purpose of overcoming this problem, surface treatment techniques such as ion beam irradiation, wet processing, plasma surface treatment, UV eximer irradiation, pulse ion irradiation or the like may be required. Among these surface treatment techniques, in particular, the plasma surface treatment technique may be performed by striking various kinds of energy and particles (for example, electrons, atoms, activated species, ions, excited molecules, excited atoms, etc.) against the surface of the wafer. Due to this physical impact, surface roughness is increased and therefore adhesion is improved. In addition, the plasma surface treatment technique may use various kinds of gases alone or in combination, thereby achieving various surface characteristics which could not be achieved by conventional methods. Further, since this plasma surface treatment technique is a dry process which uses no water, unlike other related surface treatment techniques, it provides little environmental contamination. Plasma surface treatment can change only surface characteristics without changing mechanical properties of the material, such as strength, modulus of elasticity, etc.

Adhesion between silicon and metal is affected by surface adhesion characteristics. The surface adhesion characteristics are, in turn, affected by variables such as the composition of a thin film and the substrate, the type of thin film, the structure of the thin film, the type of substrate, the shape of the substrate, the kind of bonding occurring at an interface, other phenomenon occurring at the interface (for example, a natural oxide film, reactants, etc.), the surface state of the substrate (for example, surface roughness, effective area, etc.), contaminants existing on a surface (for example, chemical absorbate, physical absorbate, organic contaminants, etc.), and the like.

Among these variables, the composition (material) of the thin film and the substrate, type and structure of the thin film, type and shape of the substrate are important factors which always affect the characteristics of a device, and are not variable options for controlling surface adhesion. Therefore, the adhesion between the silicon and the metal should be improved through development of a process for controlling contaminants on the substrate, surface roughness, effective areas, etc.

However, as one example of the above-described plasma surface treatment, when the surface treatment is to be made using argon (Ar) plasma or the like as shown in FIGS. 1A to 1D, argon remaining on a surface by argon sputtering as shown in FIG. 1A does not react with different metals such as titanium (Ti) shown in FIG. 1B and aluminum (Al) shown in FIG. 1C. This may result in a peeling effect as shown in FIG. 1D.

Surface roughness can be slightly controlled through a process of oxidizing and removing a surface using heat treatment such as in a furnace. However, a BEOL (Back-End-Of-Line) process for forming backside metal cannot use a pre-high temperature process, as seen in a graph of FIG. 2 showing a change in temperature in a metal thin film process, which may result in incomplete removal of argon or the like remaining on a surface.

### SUMMARY

Embodiments relate to a method for manufacturing a semiconductor device, and more particularly, to a method for manufacturing a semiconductor device, which is capable of removing hydrogen from a surface of a wafer by controlling surface roughness to a desired level by treating the surface using hydrogen remote plasma (HRP) and a rapid thermal process (RTP) after subjecting a backside of the wafer to a grinding process.

Embodiments relate to a method for manufacturing a semiconductor device which may be capable of preventing a peeling effect from occurring on a wafer surface by removing hydrogen from the wafer surface by controlling surface roughness to a desired level by treating the wafer surface using hydrogen plasma and a rapid thermal process (RTP) after subjecting a backside of the wafer to a grinding process.

Embodiments relate to a method for manufacturing a semiconductor device which may include: performing a grinding process on a back side of a wafer, performing a first plasma process and a rapid thermal process sequentially after performing the grinding process, performing a second plasma process after performing the rapid thermal process, and performing a metal thin film process after performing the second plasma process.

Embodiments also relate to an apparatus configured to perform a grinding process on a back side of a wafer, perform a first plasma process and a rapid thermal process sequentially after the grinding process, perform a second plasma process after the rapid thermal process, and perform a metal thin film process after the second plasma process.

### DRAWINGS

FIGS. 1A to 1D are views showing a peeling mechanism by argon (Ar) plasma and a metal thin film process.

FIG. 2 is a view showing a change in temperature in a metal thin film process in the related art.

FIG. 3 is a flowchart showing the entire process for manufacturing a power device according to embodiments.

FIGS. 4A to 4D are views showing a peeling mechanism by nitrogen (N2) plasma and a metal thin film forming process according to embodiments.

FIG. 5 is a view showing a change in temperature in a metal thin film process according to embodiments.

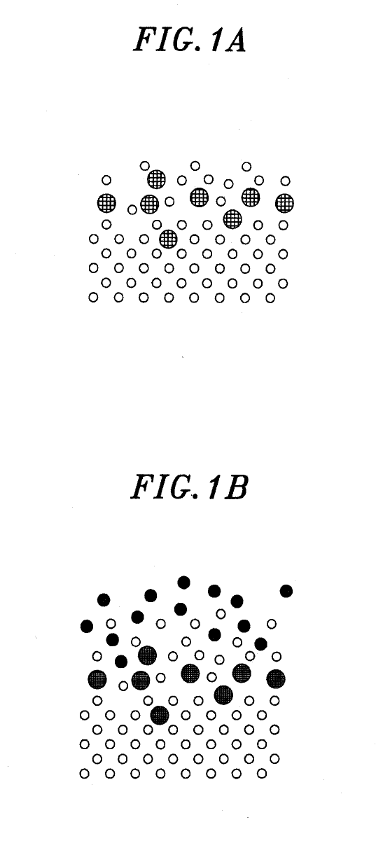

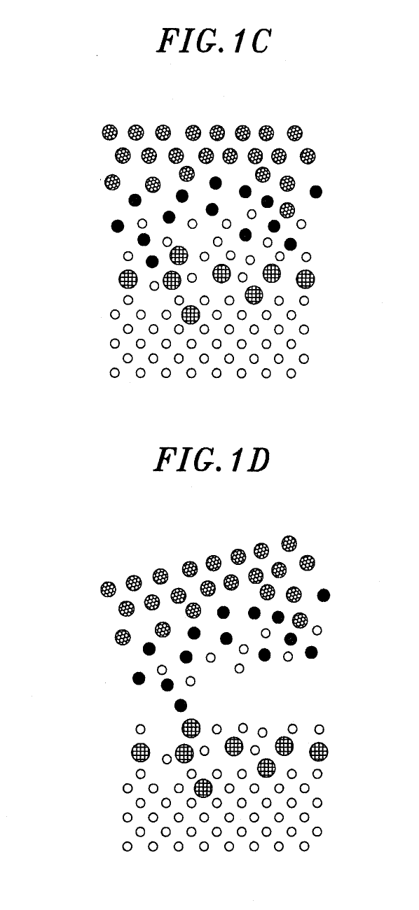

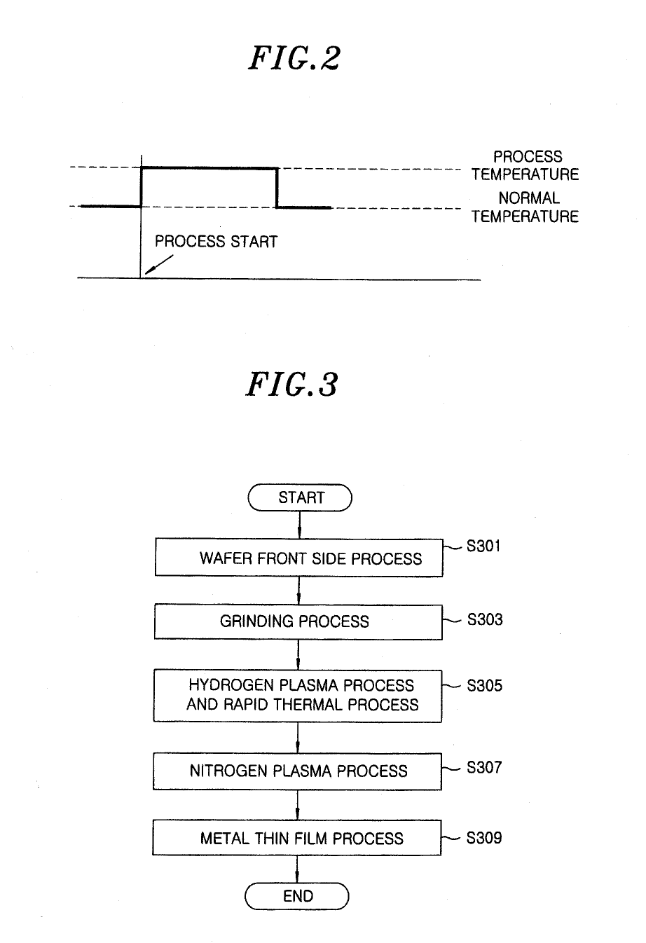

### DESCRIPTION

FIG. 3 is a flowchart showing the entire process for manufacturing a power device according to embodiments. Referring to FIG. 3, in manufacturing a semiconductor power device, after completion of a process for a wafer front side in step S301, a wafer back side may be subjected to a grinding process in step S303 to thin its overall thickness. The grinding process may improve device characteristics such as a heat generation characteristic of the power device.

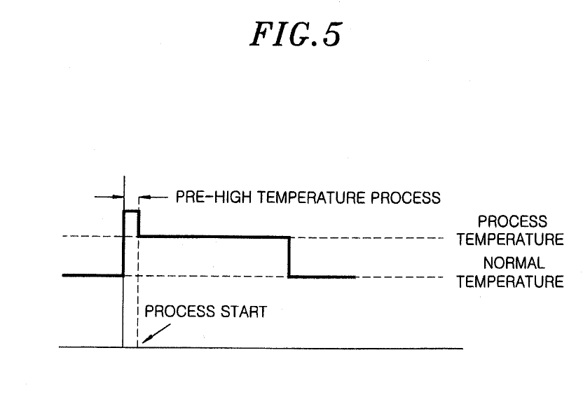

After thinning the wafer with the grinding process in step S303, a hydrogen plasma process and a rapid thermal process (RTP) may be performed in step S305. Since the volatility of byproducts which may be produced by the hydrogen plasma process is high [for example, silane (SiH₄) has volatility of melting point of −185° C. and boiling point of −112° C. and disilane (Si₂H₆) has volatility of melting point of −132° C. and boiling point of −14° C.], it is difficult to improve surface roughness, and hydrogen remaining on a surface, although rarely possible, may cause a peeling effect. Accordingly, hydrogen remaining on the surface may be removed from the surface by performing an RTP as a pre-high temperature process, as shown in FIG. 5 illustrating a change in temperature in a metal thin film process.

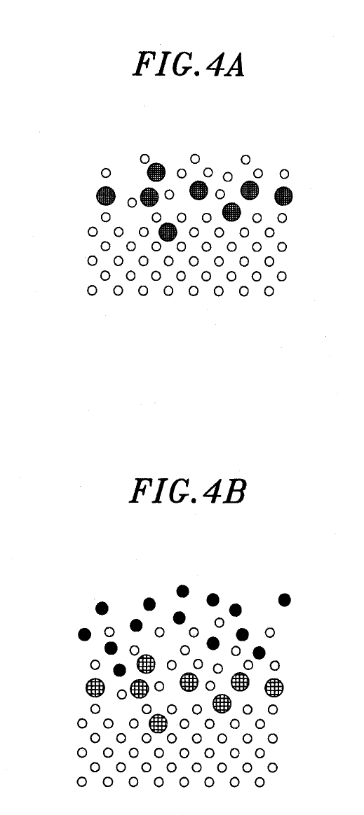

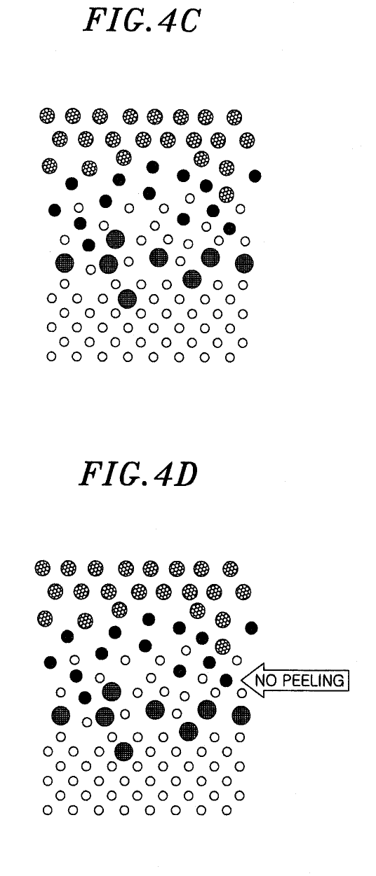

Next, after performing the hydrogen plasma process and RTP in step S305, a nitrogen plasma process may be performed by nitrogen (N₂) sputtering shown in FIG. 4A to cause a surface reaction in step S307. That is, the nitrogen plasma process causes a chemical reaction to form a type of silicon nitride film (SiN) or, silicon oxynitride film (SiON), thereby helping to increase adhesion. Here, in the nitrogen plasma process, the surface reaction may be accelerated by performing an RTP, and thus adhesion of metal with the wafer back side is improved.

Next, a process of forming a metal thin film may be performed in step S309. Specifically, a titanium (Ti) forming process as shown in FIG. 4B and an aluminum (Al) forming process as shown in FIG. 4C may be performed while decreasing temperature, so that a peeling effect is prevented as shown in FIG. 4D. The reason for decreasing temperature is that adhesion between the wafer back side and the metal thin film may be weakened if temperature rises during the metal thin film process.

As described above, in embodiments, a grinding process may be performed on a back side of a wafer. Then a surface treatment may be performed using a hydrogen plasma and an RTP to control a surface roughness to a desired level and to remove hydrogen from the wafer surface, thereby preventing a peeling effect which may occur on the wafer surface. Also, in embodiments, by performing the surface treatment using an HRP and an RTP after performing the grinding process on the wafer back side, it is possible to carry out a high temperature process which could not be used in an existing BEOL process for forming backside metal.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
performing a grinding process on a back side of a wafer;
performing a first plasma process and a rapid thermal process sequentially after performing the grinding process;
performing a second plasma process after performing the rapid thermal process; and
performing a metal thin film process after performing the second plasma process.

2. The method of claim 1, wherein the first plasma process uses hydrogen gas.

3. The method of claim 1, wherein the rapid thermal process removes hydrogen from the surface of the wafer.

4. The method of claim 1, wherein the first plasma process produces silane gas.

5. The method of claim 1, wherein the first plasma process produces disilane gas.

6. The method of claim 1, wherein the second plasma process uses nitrogen gas.

7. The method of claim 1, wherein the second plasma process is performed by nitrogen sputtering.

8. The method of claim 1, wherein the second plasma process produces a silicon nitride film on the backside of the wafer.

9. The method of claim 1, wherein the second plasma process produces a silicon oxynitride film on the backside of the wafer.

10. The method of claim 1, wherein the metal thin film process includes a titanium forming process and an aluminum forming process.

11. An apparatus configured to:
perform a grinding process on a back side of a wafer;
perform a first plasma process and a rapid thermal process sequentially after the grinding process;
perform a second plasma process after the rapid thermal process; and
perform a metal thin film process after the second plasma process.

12. The apparatus of claim 11 configured to use hydrogen gas in the first plasma process.

13. The apparatus of claim 11 configured to remove hydrogen from the surface of the wafer during the rapid thermal process.

14. The apparatus of claim 11 configured to produce silane gas during the first plasma process.

15. The apparatus of claim 11 configured to produce disilane gas during the first plasma process.

16. The apparatus of claim 11 configured to use nitrogen gas during the second plasma process.

17. The apparatus of claim 11 configured to perform the second plasma process by nitrogen sputtering.

18. The apparatus of claim 11 configured produce a silicon nitride film on the backside of the wafer during the second plasma process.

19. The apparatus of claim 11 configured to produce a silicon oxynitride film on the backside of the wafer during the second plasma process.

20. The apparatus of claim 11 configured to include a titanium forming process and an aluminum forming process in the metal thin film process.
